(19) United States
(12) Patent Application Publication
(10) Pub. No.: US 2026/0099012 A1
(43) Pub. Date: Apr. 9, 2026

(54) HYBRID-BONDED IC DIE HAVING TOPOGRAPHIC SURFACE FEATURES

(71) Applicant: Intel Corporation, Santa Clara, CA (US)

(72) Inventors: Adel A. Elsherbini, Chandler, AZ (US); Brandon M. Rawlings, Chandler, AZ (US); Veronica A. Strong, Brussels (BE); Henning Braunisch, Phoenix, AZ (US); Haisheng Rong, Pleasanton, CA (US); James E. Jaussi, Hillsboro, OR (US); Feras Eid, Chandler, AZ (US); Georgios C. Dogiamis, Chandler, AZ (US); Nada Sekeljic, Hillsboro, OR (US); John Heck, Berkeley, CA (US); Harel Frish, Albuquerque, NM (US)

(73) Assignee: Intel Corporation, Santa Clara, CA (US)

(21) Appl. No.: 18/898,424

(22) Filed: Sep. 26, 2024

(51) Int. Cl. H01L 23/00; G02B 6/42; H01L 21/768; H01L 23/544; H01L 25/16

(52) U.S. Cl. CPC G02B 6/4206; H10W 46/00; H10W 90/00; H10W 20/074; H10W 20/081; H10W 46/301; H10W 80/312; H10W 80/327; H10W 90/792

(57) ABSTRACT

Composite IC die structures comprising a first IC die that has a first region directly bonded to a second IC die across a hybrid-bond interface and a topographic feature extending from a second region of the first IC die. In some examples, a hybrid bond interface is fabricated prior to forming a topographic IC die feature. In other examples, a hybrid bond interface is fabricated after forming a topographic IC die feature. A PIC die comprising a planar optical waveguide further includes an optical coupler protruding from a region of the die. In another region of the PIC die metallization features are embedded with a dielectric material suitable for forming a hybrid bond with a surface of an EIC die. Scaling of the directly bonded interconnections between the PIC and EIC die may facilitate further disintegration of the optical and electrical domains within a heterogenous chip/chiplet assembly.

### BACKGROUND

Integrated circuit (IC) die can be assembled with solder attachment techniques where solder features are brought into contact to join dies to a host or base substrate structure. However, solder assembly techniques are difficult to scale below solder-bonded feature pitches that are in the tens of microns (e.g., 10-25 μm).

IC die may instead be assembled with hybrid bonding techniques where metallic bond sites of an IC die are directly interdiffused with corresponding metallic bond sites of a host or base substrate structure. Such bonding is referred to as “hybrid” because a bond also forms between dielectric materials adjacent to the metallic bond sites. During a hybrid bonding process, components (e.g., dies) having corresponding bond sites, are brought together to interface with one another. At room temperature, dielectric material adheres sufficiently to establish an initial bond (e.g., due to Van der Waals forces). A thermal anneal may then fuse complementary metallic bond sites, and also increase the strength of the dielectric material bond interface. Hybrid bonding techniques are scalable well below bonded feature pitches of 1 μm.

However, some IC die may have surface features with large-scale topography (i.e., protruding 5-50 μm from the surrounding surface). For example, a micro-electro-mechanical system (MEMS) IC die may have cantilevers, mirror arrays, or other physical sensors and actuators on at least a portion of the die surface. A photonic integrated circuit (PIC) die is another example of an IC die that may have large-scale surface feature topography. Photonic integrated circuits (PICs) are increasingly important in high-performance computing, data center, and cloud computing applications for their massive communication bandwidth. SiPh PICs may include micron-scale optical waveguides fabricated on substrates comprising silicon. Optical interfaces between the micron-scale PIC waveguides and off-chip optical fibers may comprise one or more optical coupling features on the PIC die that have large-scale surface topography.

While die surface features with large-scale topography may be not pose any issue for solder-based die assemblies since solder features having very large z-heights, such topographic surface features can pose an issue for hybrid bonding and may hinder electrical interconnect feature scaling for such IC die. Accordingly, hybrid-bond architectures and techniques that can accommodate IC die with large-scale topographic surface features would be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram of methods 100 for fabricating and assembling an IC die with hybrid-bonding features and topographic surface features, in accordance with some embodiments;

FIG. 2 is a cross-sectional view of a PIC substrate in accordance with some embodiments;

FIG. 3A is a plan view of a PIC die with an optical device, in accordance with some embodiments;

FIG. 3B is a first cross-sectional view of the PIC die illustrated in FIG. 3A, in accordance with some embodiments;

FIGS. 4, 5, 6, 7 and 8 are second cross-sectional views of the IC die illustrated in FIG. 3B and evolving as die fabrication operations are performed, in accordance with some embodiments;

FIG. 9 is a cross-sectional view of a PIC die hybrid bonded to an EIC die, in accordance with some embodiments;

FIG. 10 is a cross-sectional view of a multi-chip assembly including the hybrid-bonded die assembly illustrated in FIG. 9, in accordance with some embodiments;

FIG. 11 is a flow diagram of methods for fabricating and assembling an IC die with hybrid-bonding features and topographic surface features, in accordance with some alternative embodiments;

FIGS. 12, 13, 14 and 15 are cross-sectional views of an IC die evolving as die fabrication operations are performed, in accordance with some alternative embodiments;

FIG. 16 is a cross-sectional view of a PIC die hybrid bonded to an EIC die, in accordance with some alternative embodiments;

FIG. 17 is a cross-sectional view of a multi-chip assembly including the hybrid-bonded die assembly illustrated in FIG. 16, in accordance with some alternative embodiments;

FIG. 18 illustrates a computing platform comprising the OEIC illustrated in FIG. 10 or FIG. 17, in accordance with some embodiments; and

FIG. 19 is a functional block diagram of an electronic computing device, that may implement one or more of the components of the computing platform illustrated in FIG. 18, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

As described further below, hybrid-bonding surface features are fabricated on a first surface region of an IC die adjacent to a second region of the IC die that includes a large topographic surface feature. In accordance with some embodiments, hybrid-bonding surface features are fabricated on an IC die and then protected during subsequent fabrication of the topographic surface feature. In accordance with some alternative embodiments, a topographic surface feature is fabricated on an IC die and then encapsulated within a fill material. Electrical vias are formed through the fill material followed by the fabrication of hybrid-bonding surface features. A portion of the encapsulant may then be removed to re-expose the topographic surface feature. Through the practice of embodiments herein, an IC die, such as PIC die or MEMs die, may be hybrid bonded to a host. In some examples where the IC die is a PIC die including an integrated (on-chip) optical coupler, the host is an electrical IC (EIC). A bonded PIC-EIC die composite, benefiting from the tight-pitched electrical interconnects possible through hybrid bonding, may further facilitate the disintegration of the optical and electrical domains within heterogeneous IC systems.

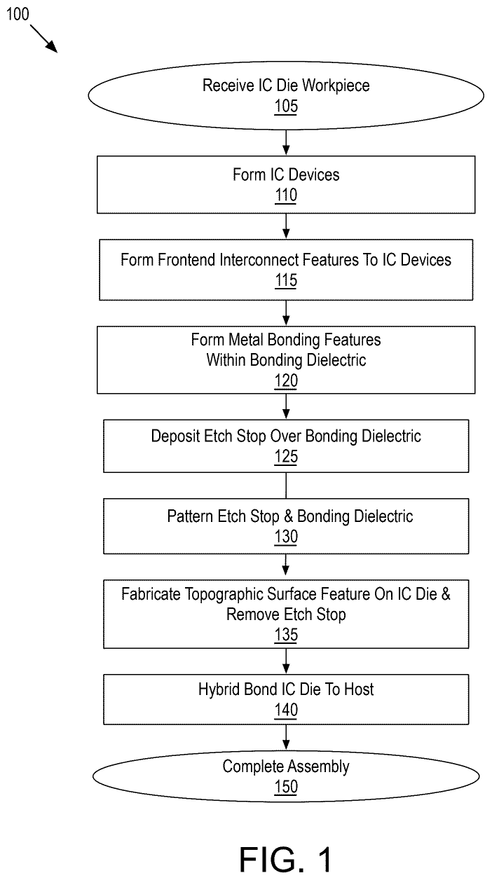

FIG. 1 is a flow diagram of methods 100 for fabricating and assembling an IC die with hybrid-bonding features and topographic surface features, in accordance with some embodiments. Methods 100 may be practiced to fabricate an IC die having one or more of the structural attributes described herein. Although in exemplary embodiments the IC die is a PIC die, methods 100 may be practiced to fabricate other IC dies with comparable topographic surface features to similarly facilitate hybrid bonding. Although some examples are further described in the context of SiPh PIC implementations, the architectures and techniques so described may also be implemented in alternative substrate technologies (e.g., III-V PICs) and/or for alternative IC die technologies (e.g., MEMs, VR inductors, etc.) without departing from the principles disclosed herein.

Methods 100 begin at input 105 where an IC die workpiece is received. The workpiece may comprise a wafer or panel, for example of a semiconductor material suitable for the fabrication of IC devices. In some exemplary PIC embodiments, the IC die workpiece received at input 105 is a semiconductor on insulator (SOI) workpiece. The SOI workpiece comprises a semiconductor substrate material and a buried insulator layer, for example between a top (front) side substrate semiconductor material layer and another substrate semiconductor material layer on a bottom (back) side of the insulator layer.

Methods 100 continue at block 110 where IC devices are fabricated. In exemplary PIC embodiments, one or more r optical devices are fabricated in the IC die workpiece. In some SiPH embodiments, planar optical waveguides are fabricated within a top side semiconductor substrate material layer. Other optical devices, such as optical diodes (emitting or detecting), optical multiplexers and demultiplexers (e.g., further comprising one or more of interferometers, Echelle gratings, etc.) may also be fabricated at block 110 and optically interconnected to each other through one or more planar optical waveguides. In other embodiments, one or more electrical devices, such as resistors, inductors, transistors, memory cell arrays, etc. may be fabricated at block 110. In some further embodiments, at block 110 one or more electrical devices may be fabricated in conjunction with one or more optical devices. For example, a Mach-Zehnder interferometer may be fabricated at block 110 which comprises optical waveguide arms and resistive heaters to modulate the phasing of light propagated through the optical waveguide arms. The resistive heaters may be part of an electrical device integrated on-die with the optical device, all of which may be fabricated at block 110. Any thin film processing known to be suitable for fabricating IC die devices may be practiced at block 110. For example, any number of thin film deposition, photolithographic patterning and etching processes may be practiced at block 110.

Methods 100 continue at block 115 where electrical interconnects are formed in an IC die to electrically interconnect electrical terminals of the devices fabricated at block 110. Any thin film processing techniques known to be suitable for fabricating IC die devices may be practiced at block 115 to form integrated circuitry on an IC die. For example, any number of thin film deposition, photolithographic patterning and etching processes may be practiced at block 115.

At block 120 a thin film layer of dielectric material suitable for direct bonding is deposited over the IC die and metal bonding features are formed within the bonding dielectric. Metal bonding features may be formed within any region of the IC die that is to be directly bonded to a complementary hybrid-bonding surface of a host component. The metal bonding features formed at block 120 are electrically coupled to underlying metallization features of the IC die. The metal bonding features may be, for example, vias landed on (or intersecting) an underlying metallization feature, such as a local interconnect line, resistive element, or capacitor pad, for example. Metal bonding features fabricated at block 120 may also comprise pads of an area larger than an underlying via that further couples the pad to an underlying metallization feature.

The hybrid bonding surface prepared at block 120 may then be protected with a layer of sacrificial material deposited at block 125. The sacrificial material is to be subsequently removed to reveal the hybrid bonding surface after topographic features are fabricated in other regions of the IC die adjacent to the hybrid bonding surface. The sacrificial material may have any chemical composition offering suitable protection from the processing performed to form the topographic features and can be subsequently removed from the underlying hybrid bonding surface. Accordingly, the sacrificial material has a different composition than that of the hybrid bonding surface. In some examples, the sacrificial material is of a composition that will function as an etch stop for one or more etch processes performed in the IC die fabrication process.

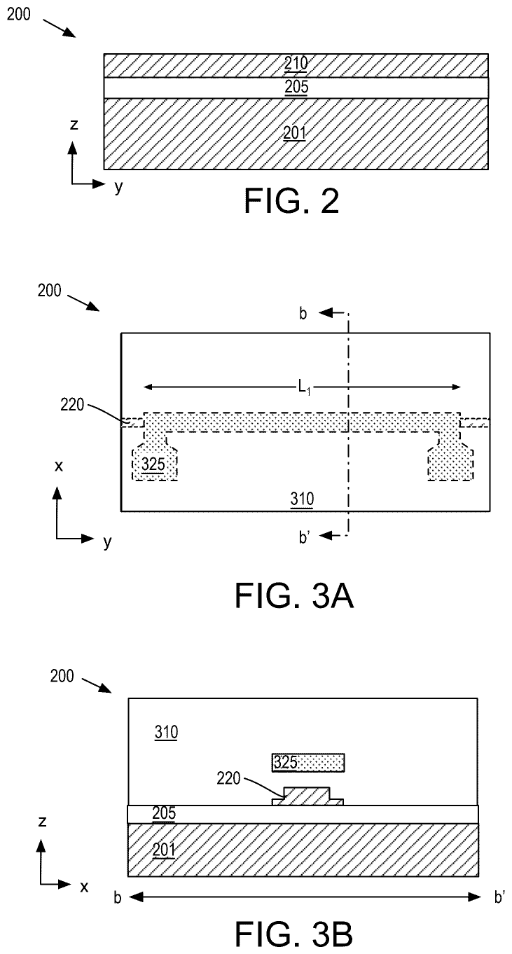

FIGS. 2-5 illustrate some exemplary PIC die embodiments evolving as methods 100 (FIG. 1) are practiced through block 125. Referring first to FIG. 2, a PIC structure 200 comprises a portion of a substrate material layer 201. In exemplary embodiments, substrate material layer 201 comprises substantially monocrystalline silicon. Substrate material layer 201 is a base layer of an SOI substrate material stack further comprising a buried insulator material layer 205. In exemplary embodiments, where substrate material layer 201 is substantially pure silicon, insulator material layer 205 is advantageously predominantly silicon and oxygen and may be essentially pure silicon dioxide (e.g., SiO₂). One or more additional substrate material layers may be over insulator material layer 205. In the example illustrated in FIG. 2, buried insulator material layer 205 is between substrate material layer 201 and a device material layer 210. In some embodiments where substrate material layer 201 is substantially monocrystalline silicon, device material layer 210 is also substantially monocrystalline silicon.

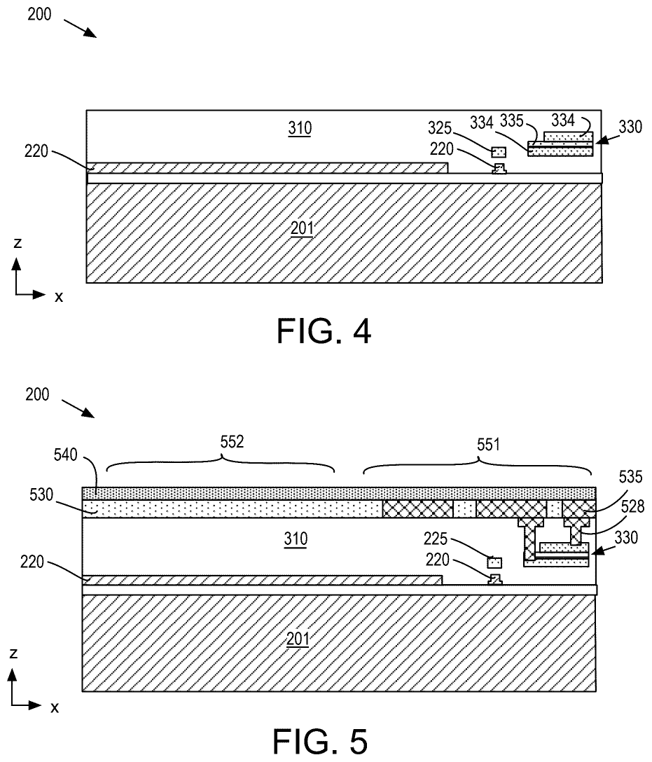

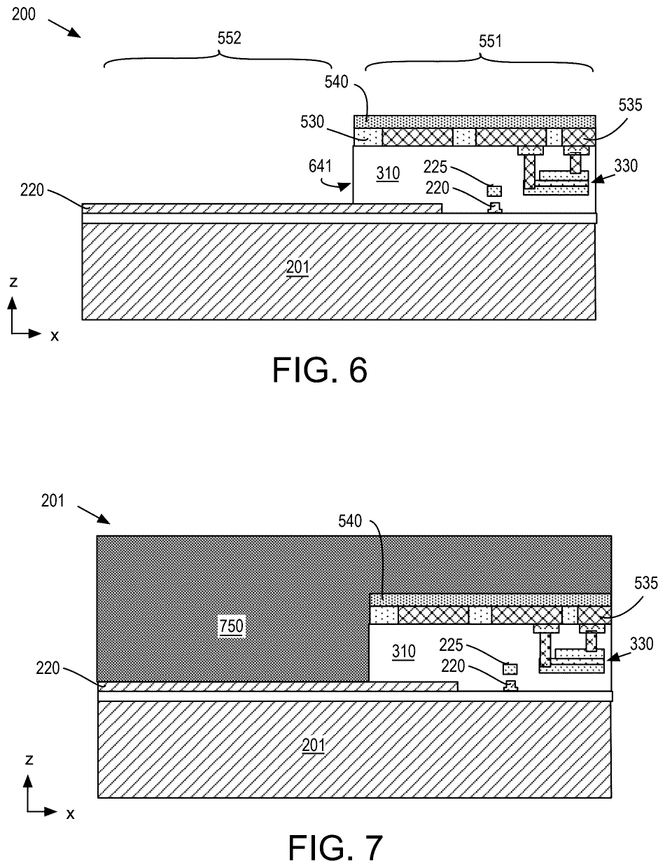

FIG. 3A is a plan view of PIC structure 200 following fabrication of optical and electrical devices, for example at block 110 of methods 100 (FIG. 1). FIG. 3B is a cross-sectional view of PIC structure 200 along the b-b′ line illustrated in FIG. 3A. As shown, PIC structure 200 now includes a dielectric material 310 over insulator material layer 205 and over an optical waveguide 220 that as been etched from device layer 210 (FIG. 2). Optical waveguide 220 may be a portion of any known optical device as embodiments are not limited in this respect. Dielectric material 310 may have any composition. In some exemplary embodiments, dielectric material 310 is silicon-based, and may be predominantly silicon and oxygen (i.e., SiOₓ) with one example being silicon dioxide (SiO₂).

As shown in FIG. 3A, a heater element 325 has been fabricated over the spans a longitudinal length L₁ of waveguide 220. Length L₁ may vary, for example from hundreds of nanometers (nm) to hundreds of microns (μm). In the illustrated example, heater element 325 comprises two via lands at opposite ends of length L₁ where electrical power is to be applied. Heater element 325 is one example of an electrical device that may be fabricated into an IC die. Heater element 325 may comprise any material having a suitable electrical resistivity to convert electrical power into thermal energy during operation of PIC structure 200. In some embodiments, heater element 325 comprises a metal or metal alloy, such as W or Ti. Heater element 325 may also comprise other materials, such as semiconductor materials having a suitable resistivity.

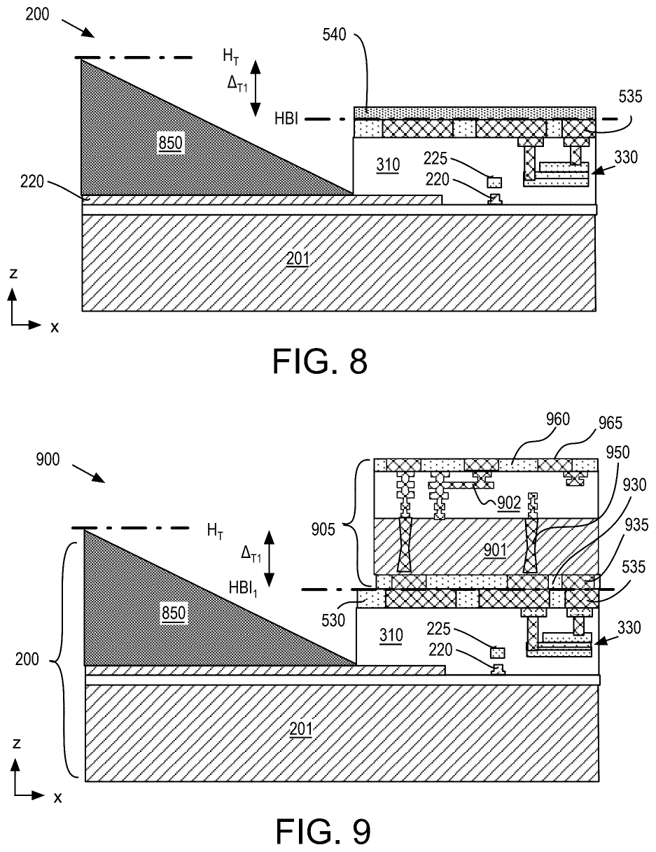

FIG. 4 further illustrates fabrication of frontend interconnect circuitry comprising one or more levels of metallization to couple together electrical and opto-electrical devices fabricated in an IC. Heater element 325 may comprise resistive portion of an interconnect line, for example. A metal-insulator-metal (MIM) capacitor 330 is also illustrated as another example of an electrical device that may be fabricated within frontend metallization levels of PIC structure 200. Frontend metallization features may be formed by practicing any suitable thin film IC die fabrication techniques. Heater element 325 and electrodes of MIM capacitor 330 may comprise a thin film of metal 334 (e.g., W, WNx, Ti, TiNx, etc.) that may be deposited and etched into lines and/or electrodes, etc. One or more thin film dielectric material layers (e.g., MIM capacitor insulator 335) may be deposited over the frontend metal features.

As further illustrated in FIG. 5, a bonding dielectric material 530 has been deposited over IC die dielectric material 310. Bonding dielectric material 530 may have any chemical composition suitable for hybrid bonding. Bonding dielectric material 530 is advantageously an inorganic material, for example comprising at least 20 atomic % of one or more of silicon, oxygen, or nitrogen. In some embodiments, bonding dielectric material 530 is primarily silicon and oxygen (e.g., SiO₂), primarily silicon and nitrogen (e.g., Si₃N₄), or primarily silicon, oxygen and nitrogen (e.g., SiOₓN_{y}), any of which may further comprise one or more dopants, such as carbon.

Bonding metallization features 535 are embedded within, and substantially co-planar with, bonding dielectric material 530. Bonding metallization features 535 may have any chemical composition suitable for forming a bond with another metallization feature, for example through interdiffusion. In some examples, bonding metallization features 535 comprise predominantly copper (Cu) and may be formed with a damascene process. Bonding metallization features 535 are coupled to underlying metallization features, such as resistive element 225, electrodes of MIM capacitor 330, etc. Bonding metallization features 535 may be in direct contact with underlying frontend metallization of an alternative composition (e.g., W, or Ti, etc.), or as illustrated in FIG. 5, bonding metallization features 535 may be coupled to underlying frontend metallization through intervening Cu-based via metallization 528. As shown, bonding metallization features 535 are confined to a region 551 of PIC structure 200 adjacent to region 552 that is reserved for subsequent fabrication of one or more topographic die features.

FIG. 5 further illustrates a protection material layer 540. The thickness and composition of protection material layer 540 may vary with implementation. Protection material layer 540 may be a dielectric or metallic compound, for example. In some embodiments, protection material layer 540 is an amorphous carbon thin film material. In other embodiments, protection material layer 540 is primarily silicon and oxygen (e.g., SiO₂), primarily silicon and nitrogen (e.g., Si₃N₄), or primarily silicon, oxygen and nitrogen (e.g., SiOₓN_{y}) with the caveat that the composition is distinct from the underlying bonding dielectric material 530. In still other embodiments, protection material layer 540 comprises a metallic compound (e.g., TaNₓ, WNₓ, TiNₓ, etc.).

Returning to FIG. 1, methods 100 continue with IC die fabrication at block 130 where the bonding dielectric material and any overlying protective etch stop layer is patterned to remove these materials from a region of the IC die that is not to be hybrid bonded with a host component. The subtractive patterning process(es) practiced at block 130 may remove any underlying material layers as needed to couple the topographic features fabricated at block 135 with underlying IC die structures. For example, any of the optical or electrical IC devices fabricated at block 110 may be exposed at block 130. Similarly, any frontend interconnect metallization features fabricated at block 115 may also be exposed at block 130.

At block 135 one or more thin film material layers are deposited over the IC die and patterned into one or more topographic surface features. Any IC fabrication processes, such as material depositions, photolithography, material etching, and planarization may be performed at block 135. During all such processing, the etch stop material layer deposited at block 125 protects the underlying hybrid-bonding surface. Upon fabricating the topographic surface features, IC die fabrication may be completed with the removal of the protective etch stop layer, exposing the hybrid-bonding surface adjacent to the topographic surface features.

Methods 100 continue at block 140 where the IC die is directly bonded to a host component, for example according to any known hybrid-bonding technique. The resulting composite die structure may then be further integrated with any other IC die, package substrates, etc. to complete an assembly at output 150.

FIGS. 6-10 illustrate some exemplary PIC die embodiments evolving as methods 100 (FIG. 1) are practiced through output 150. Referring first to FIG. 6, PIC structure 200 has been subtractively patterned by etching through protection layer 540, through bonding dielectric material 530, as well as through at least a portion of dielectric material 310 within region 552. Any photolithographically defined mask material and etch processes (e.g., anisotropic plasma) may be practiced, for example to expose optical waveguide 220 (or a cladding material thereof). Following the patterning process, a recess sidewall 641 demarks the boundary between bonding region 551 and topographic feature region 552.

In FIG. 7, PIC structure 200 has evolved to further include an optical material 750, which has been deposited and planarized over IC die regions 551 and 552. Optical material 750 may have any chemical composition with suitable optical properties (e.g., refractive index, etc.).

Optical material 750 may be a dielectric material of different composition that dielectric material 310. Optical material 750 may, for example, be primarily silicon and oxygen (e.g., SiO₂), primarily silicon and nitrogen (e.g., Si₃N₄), or primarily silicon, oxygen and nitrogen (e.g., SiOₓN_{y}). In some advantageous embodiments, optical material 750 is Si₃N₄.

In FIG. 8, optical material 750 has been patterned into an optical coupler 850, for example having at least a thickness taper along its length to couple optical mode energy from a larger diameter mode size associated with an optical waveguide external of the PIC die to an optical mode size associated with waveguide 220. Optical coupler 850 may also have a taper within the x-y plane, or not. Optical coupler 850 may have alternative structures, for example comprising a taper only within the x-y plane, or instead comprising a periodic grating, etc. In the example shown in FIG. 8, optical coupler 850 has a maximum topographic height H_{T} from a reference plane (e.g., coincident with waveguide 220). Topographic height H_{T} is greater than a height of the hybrid-bonding interface HBI underlying protection layer 540. Although topographic height H_{T} may vary with implementation, in some examples height H_{T} is 5 μm or more. A difference ΔT₁ between maximum topographic height H_{T} and the height of bonding interface HBI may range from 0.5 μm-2 μm, or more. PIC structure 200 may then be completed for assembly by removing protection material 540, either before or after singulation of PIC die.

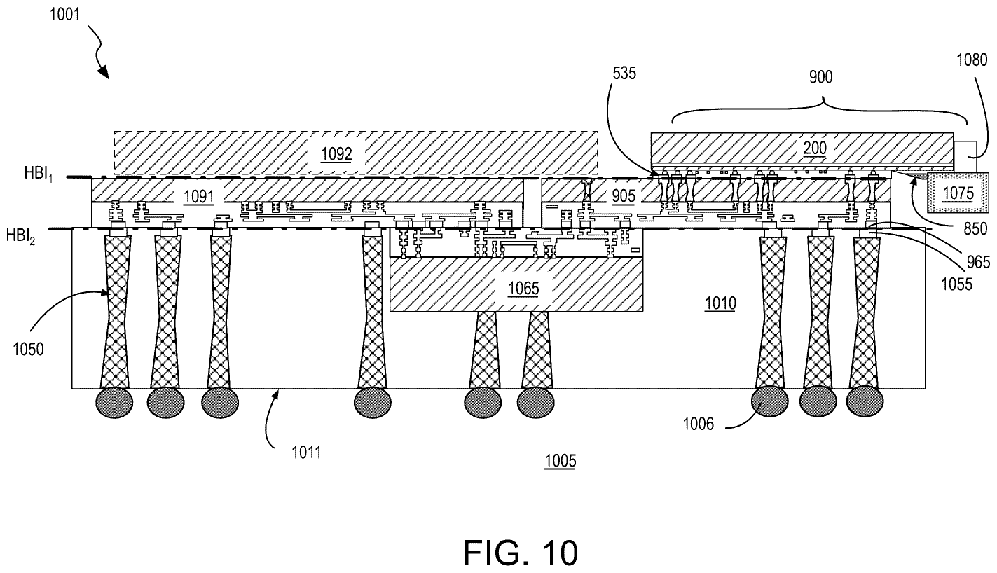

FIG. 9 is a cross-sectional view of a composite die structure 900 resulting from hybrid bonding a PIC die comprising PIC structure 200 to an EIC die 905, in accordance with some embodiments. As shown, EIC die 905 includes electrical devices (e.g., transistors) fabricated upon a substrate 901 (e.g., silicon), which are interconnected into circuitry by IC die interconnect metallization 902. EIC die 905 further includes through-die vias 950 which couple IC die circuitry to hybrid-bonding metallization features 935 embedded within a hybrid-bonding dielectric material 930 on a first (e.g., back) side of EIC die 905. At a first hybrid-bond interface HBI₁, dielectric material 930 and metallization features 935 are in direct contact with corresponding metallization features 535 and dielectric material 530. Additional hybrid-bonding metallization features 965 embedded within another hybrid-bonding dielectric material 960 may be on a second (e.g., front) side of EIC die 905 to facilitate further electrical coupling to EIC die 905.

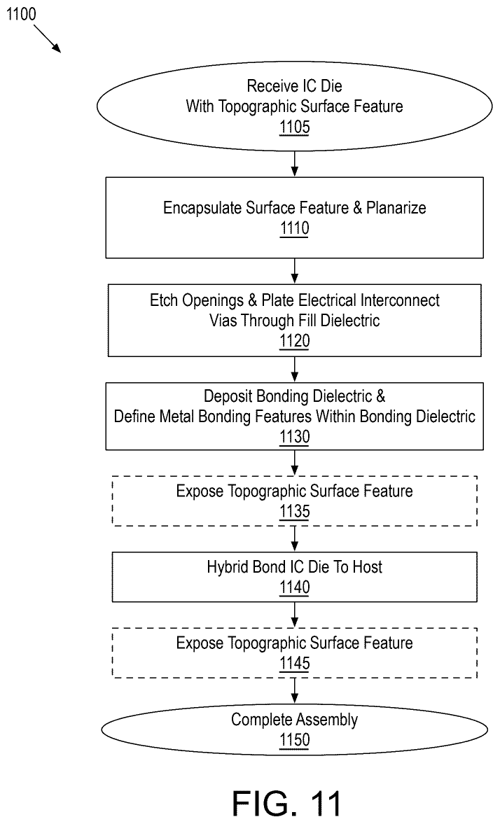

FIG. 10 is a cross-sectional view of a multi-chip assembly 1001, which includes the hybrid-bonded die assembly 900, in accordance with some embodiments. In this example, multi-chip assembly 1001 includes a primary substrate 1010 comprising one or more levels of RDL metallization features embedded within one or more layers of dielectric material and terminating at hybrid-bonding metallization features 1055. Metallization features 1055 may comprise one or more metals, with one exemplary metal being copper. Metallization features 1055 may have the finest metallization line: space feature pitch that can be directly patterned (e.g., <3 μm lines and spaces), for example as limited by the flatness of primary substrate 1010. Primary substrate 1010 further includes conductive through vias 1050. In some examples through vias 1050 have a lateral pitch of no more than 100 μm and may, for example, couple power from a host 1005 conveyed through solder bumps 1006 arrayed over a back side surface 1011 of primary substrate 1010. Depending on the implementation, host 1005 may be a printed circuit board (PCB), a package substrate, or any interposer suitable for the further integration of assembly 1001.

Depending on the embodiment, primary substrate 1010 may comprise a core material, such as a piece of bulk glass or a copper clad laminate, etc. Alternatively, primary substrate 1010 may be coreless. Primary substrate 1010 may further comprises dielectric material layers, which may be any of a molding compound, a spin-on material, or dry film laminate material, for example. Some dielectric material may be introduced wet/uncured into a cast and then dried/cured. Alternatively, some dielectric material may be introduced as a semi-cured dry film that is fully cured following its application to a core material. Although the composition(s) of dielectric material(s) in primary substrate 1010 may vary with implementation, in some advantageous embodiments primary substrate comprises an organic dielectric, such as, an epoxy resin, phenolic-glass, or a resinous film such as the GX-series films commercially available from Ajinomoto Fine-Techno Co., Inc. (ABF).

FIG. 10 further illustrates an example where an IC die 1065 has been assembled into a recess in primary substrate 1010. IC die 1065 may be a passive component for example only including IC die interconnect structures having a sub-micron lateral pitch. In other embodiments, IC die 1065 may include active electrical and/or optical devices. IC die 1065 may be in electrical contact a through-via 1050, or not. IC die 1065 further comprises a hybrid-bonding surface exposed at front-side of primary substrate 1010 with a remainder of IC die 1065 being substantially embedded within primary substrate 1010.

Assembly 1001 further includes IC die 1091 coupled to primary substrate 1010 and IC die 1065. IC die 1091 may be any ASIC or memory IC, for example. In some embodiments IC die 1091 is a processing unit (xPU), such as any known multi-core processor. EIC die 950, adjacent to IC die 1091, is electrically coupled to primary substrate 1010 through metallization features 965 bonded across the interface HBI₂ to metallization features 1055. Other metallization features 965 may be similarly directly bonded to metallization features of IC die 1065. IC die 1065 may therefore be electrically coupled to each of IC die 1091 and EIC 905 through interface HBI₂. EIC 905 is further coupled to a PIC die comprising PIC structure 200 through interface HBI₁, substantially as described above. Optical coupler 850, adjacent to interface HBI₂, and protruding from a surface of PIC structure 200, is further coupled to an optical fiber 1080, for example by means of a fiber connector 1075. Fiber connector 1075 may, for example, be affixed to assembly 1001 such that optical fiber 1080 is aligned with optical coupler 850.

Assembly 1001 may further include one or more additional IC die 1092, which may comprise passive and/or active electrical and/or optical devices. In some embodiments, IC die 1092 is directly bonded to a second (e.g., backside) surface of IC die 1091, for example through bonding metallization features and bonding dielectric materials joined along bonding interface HBI₁.

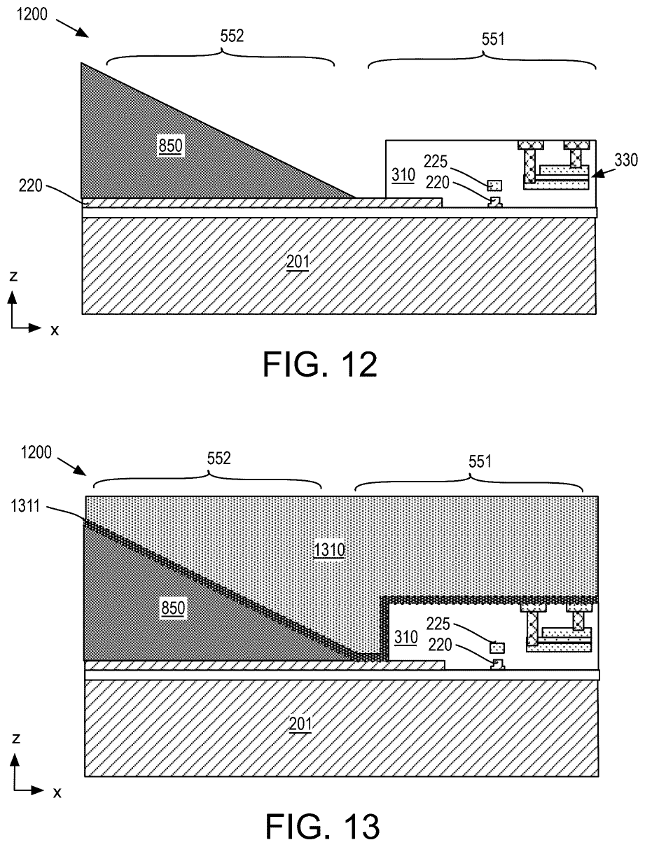

FIG. 11 is a flow diagram of methods 1100 for assembling an IC die with hybrid-bonding features and topographic surface features, in accordance with some alternative embodiments where an IC die received at input 1105 comprises a topographic surface feature but does not yet include a hybrid-bonding surface. As received, the IC die may be one of a plurality of such die on a wafer or reconstituted panel comprising a semiconductor material or glass, for example. Although dimensions of the topographic surface feature may vary with implementation, the surface feature protrudes from a remainder of the IC die surface by at least 5 μm, and may protrude by up to 10 μm, or more (e.g., 15 μm, 20 μm, etc.). The topographic surface feature may have any functionality, such as an optical coupler or a MEMs structure, and generally does not occupy an entire footprint of the IC die surface but rather only a portion or region of the surface. While remainder of the IC die surface are is available for electrical interconnects, the topographic surface feature induces IC surface topography of a magnitude that is incompatible with hybrid-bonding the electrical interconnects. The topographic surface features may be fabricated upstream of methods 1100, for example with any frontend wafer fabrication process. In some exemplary embodiments, the IC die workpiece comprises one or more PIC die structures including a semiconductor substrate material and a buried insulator layer.

Methods 1100 continue at block 1110 where the topographic surface feature is at least partially encapsulated with a fill material. Following material deposition, the fill material may be planarized, for example as part of a backend IC die fabrication process. Fill material deposited at block 1110 is advantageously one or more dielectric material layers that can be rapidly deposited to thicknesses of 5-50 μm, or more. The composition of the fill material may vary with implementation, but in some embodiments the fill material has different composition than the underlying topographic surface feature. In embodiments where multiple material layers are deposited at block 1110, an etch stop layer may be deposited directly on the underlying topographic surface feature and a second material layer may be deposited over the etch stop layer.

At block 1120, methods 1100 continue with forming via openings through the fill material deposited at block 1110 to expose underlying interconnect features that are to be electrically coupled off-chip. The via openings formed through the fill material may be at least partially filled with a conductive material, for example with a metal plating process to form interconnect vias extending through the fill material. At block 1130, a bonding dielectric material is deposited over the fill material and bonding metallization features are formed within the bonding dielectric. Although the composition of the bonding dielectric material may vary, in exemplary embodiments the bonding dielectric material has a different composition than the underlying fill material. For example, relative to the fill material, the bonding dielectric material may be of a higher film quality (e.g., having a higher density, lower porosity, and/or higher dielectric constant).

At block 1140 the IC die is directly bonded to a host component, for example according to any known hybrid-bonding technique. Optionally, before or after hybrid bonding the topographic features may be exposed by etching through bonding dielectric material and fill material from within a region of the IC die where the topographic feature is located. In some embodiments, at block 1135, a lithographic patterning process and masked etch process is practiced to expose regions of the IC die which are not to be hybrid bonded. In other embodiments, at block 1145, regions of the IC die may be etched after the hybrid-bonding process at block 1140 to expose the topographic feature. The composite die structure resulting from the bonding operations performed at block 1140 may be further integrated with any other IC die, package substrates, etc. to complete an assembly at output 1150.

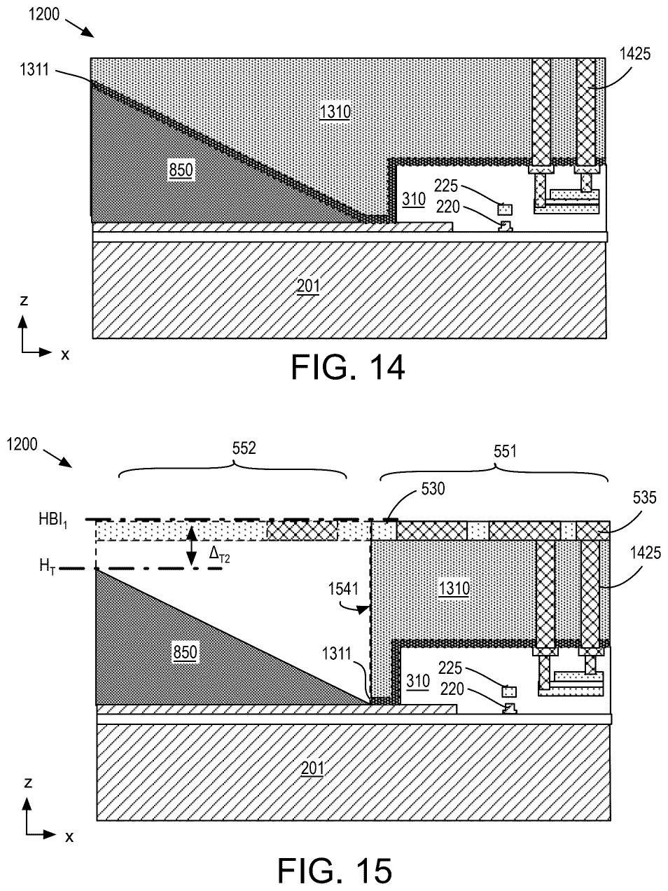

FIG. 12-17 are cross-sectional views of a PIC structure 1200 evolving as die fabrication operations are performed in the practice of methods 1100 (FIG. 11), in accordance with some alternative embodiments. Referring to FIG. 12, a PIC structure 1200 includes optical coupler 850 within region 552, for example as fabricated according to any known techniques. In the illustrated examples, PIC structure 1200 further includes MIM capacitor 330 and resistive heater 225 within region 551. Optical waveguide 220 spans both regions 551, 552. Electrical and/or optical device structures integrated on the PIC die may have any of the properties or attributes substantially as described above for PIC structure 200.

FIG. 13 further illustrates PIC structure 1200 following deposition of an etch stop material layer 1311 and a fill material 1310 over regions 551 and 552. Etch stop material layer 1311 is optional and may be employed where fill material 1310 is to be subsequently removed from over optical coupler 850, for example to ensure proper refractive index contrast. Fill material 1310 may be any dielectric material, for example having a different composition than optical coupler 850. In some embodiments, fill material 1310 is an optically lossy dielectric material and may be primarily silicon and oxygen (e.g., SiO₂), or primarily silicon, oxygen and nitrogen (e.g., SiOₓN_{y}). In some further embodiments, fill material 1310 is a carbon-doped silicon-based oxide. In other embodiments, fill material 1310 is an amorphous carbon material (α-carbon). As further illustrated in FIG. 13, a top surface of fill material 1310 has been planarized across regions 551 and 552.

In FIG. 14, PIC structure 1200 has evolved to further include conductive vias 1425 extending through fill material 1310 (and etch stop layer 1311, if present) to contact underlying metallization features. In exemplary embodiments, damascene-type processing may be performed to fabricate conductive vias 1425. In some examples, via openings are lithographically patterned and etched into fill material 1310 (and etch stop layer 1311, if present). The via openings are then filled (e.g., plated) with metallization (e.g., primarily Cu).

In FIG. 15, a bonding dielectric material 530 has been deposited over IC die fill material 1310. Bonding dielectric material 530 may have any chemical composition suitable for hybrid bonding. Bonding dielectric material 530 is advantageously an inorganic material, for example comprising at least 20 atomic % of one or more of silicon, oxygen, or nitrogen. In some embodiments, bonding dielectric material 530 is primarily silicon and oxygen (e.g., SiO₂), primarily silicon and nitrogen (e.g., Si₃N₄), or primarily silicon, oxygen and nitrogen (e.g., SiOₓN_{y}), any of which may further comprise one or more dopants, such as carbon.

Bonding metallization features 535 are embedded within, and substantially co-planar with, bonding dielectric material 530. Bonding metallization features 535 may have any chemical composition suitable for forming a bond with another metallization feature, for example through interdiffusion. In some examples, bonding metallization features 535 comprise predominantly copper and may be formed with a damascene process. Bonding metallization features 535 are coupled to underlying metallization features, such as resistive element 225, electrodes of MIM capacitor 330, etc. Bonding metallization features 535 may be in direct contact with underlying Cu-based conductive vias 1425. As shown in FIG. 15, hybrid bonding interface HBI₁ is at a height ΔT₂ above a top surface of optical coupler 850. In contrast to PIC structure 200 (e.g., FIG. 8), the top surface of optical coupler has a height H_{T} that is less than a height of interface HBI₁.

In some embodiments, bonding dielectric 530 and fill material 1310 may be retained within both regions 551, 552 and bonding metallization features 535 may extend into region 552, potentially over some portion of optical coupler 850. In other embodiments, bonding metallization features 535 are confined to region 551 of PIC structure 200. Adjacent region 552 may then be further processed to re-expose optical coupler 850, which is represented by dashed line in FIG. 15. For such embodiments, bonding dielectric 530 and a thickness of fill material 1310 may be subtractively patterned with one or more suitable etch processes. The patterning process may remove the portions of bonding dielectric 530 and fill material 1310 denoted in dashed line, forming a fill material sidewall 1541 at a boundary between hybrid-bonding region 551 and topographic surface feature region 552. As further illustrated in FIG. 15, etch stop layer 1311 may also be removed to completely expose optical coupler 850, for example to reduce optical power loss or otherwise improve performance of optical coupler 850.

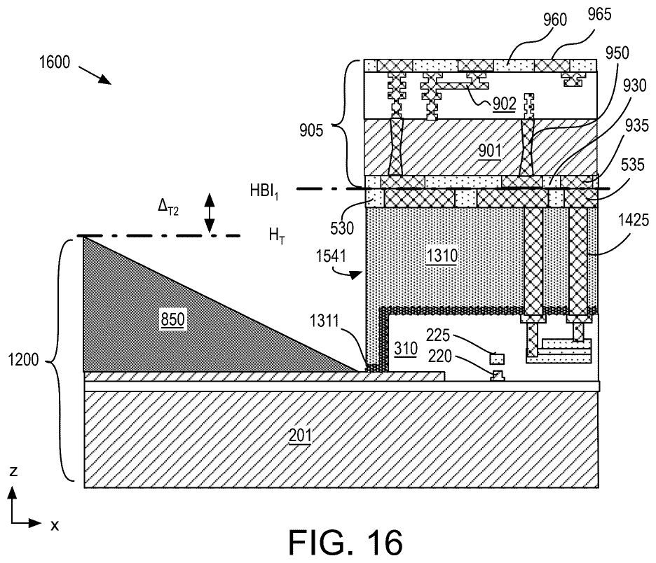

FIG. 16 is a cross-sectional view of a composite die structure 1600 comprising a PIC die that includes PIC structure 1200 hybrid bonded to EIC die 905, in accordance with some alternative embodiments. EIC die 905 includes electrical devices (e.g., transistors) fabricated upon a substrate 901 (e.g., silicon), which are interconnected into circuitry by IC die interconnect metallization 902. EIC die 905 further includes through-die vias 950 which couple IC die circuitry to hybrid-bonding metallization features 935 embedded within a hybrid-bonding dielectric material 930 on a first (e.g., back) side of EIC die 905. At a first hybrid-bond interface HBI₁, dielectric material 930 and metallization features 935 are in direct contact with corresponding metallization features 535 and dielectric material 530. Additional hybrid-bonding metallization features 965 embedded within another hybrid-bonding dielectric material 960 may be on a second (e.g., front) side of EIC die 905 to facilitate further electrical coupling to EIC die 905.

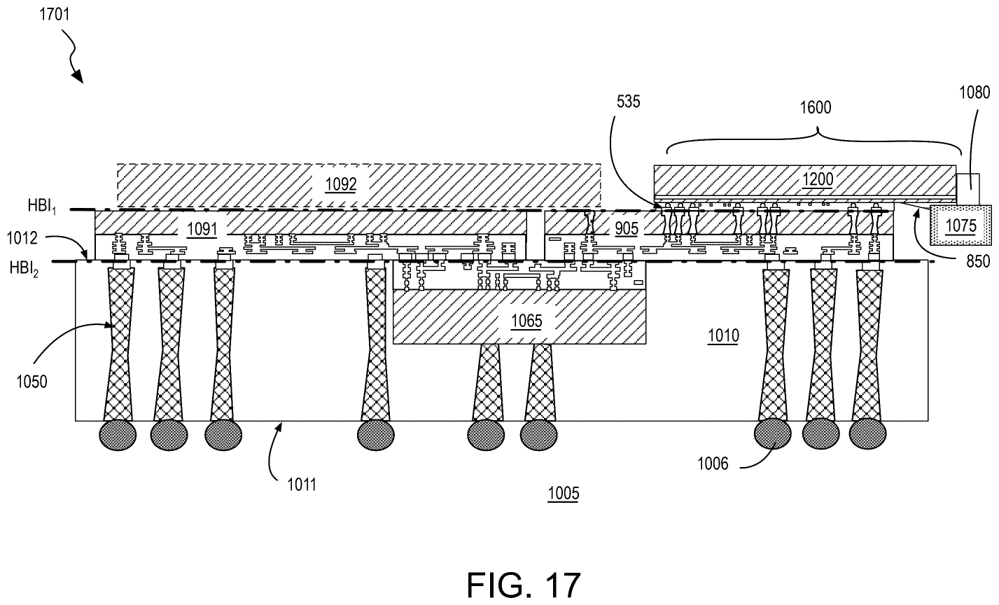

FIG. 17 is a cross-sectional view of a multi-chip assembly 1701 that includes the hybrid-bonded die assembly 1600, in accordance with some embodiments. In this example, multi-chip assembly 1701 includes primary substrate 1010 comprising one or more levels of RDL metallization features embedded within one or more layers of dielectric material and terminating at hybrid-bonding metallization features 1055. Metallization features 1055 may comprise one or more metals, such as copper. Metallization features 1055 may have the finest metallization line: space feature pitch that can be directly patterned (e.g., <3 μm lines and spaces), for example as limited by the flatness of primary substrate 1010. Primary substrate 1010 further includes conductive through vias 1050. In some examples through vias 1050 have a lateral pitch of no more than 100 μm and may, for example, couple power from a host 1005 conveyed through solder bumps 1006, which may be arrayed over a back side surface 1011 of primary substrate 1010. Depending on the implementation, host 1005 may be a printed circuit board (PCB), a package substrate, or any interposer suitable for the further integration of assembly 1001.

Depending on the embodiment, primary substrate 1010 may comprise a core material, such as a piece of bulk glass or a copper clad laminate, etc. Primary substrate 1010 may further comprises dielectric material layers, which may be any of a molding compound, a spin-on material, or dry film laminate material, for example. Some dielectric material may be introduced wet/uncured into a cast and then dried/cured. Alternatively, some dielectric material may be introduced as a semi-cured dry film that is fully cured following its application to a core material. Although the composition(s) of dielectric material(s) in primary substrate 1010 may vary with implementation, in some advantageous embodiments primary substrate comprises an organic dielectric, such as, an epoxy resin, phenolic-glass, or a resinous film such as the GX-series films commercially available from Ajinomoto Fine-Techno Co., Inc. (ABF).

FIG. 17 further illustrates an example where an IC die 1065 has been assembled into a recess in primary substrate 1010. IC die 1065 may be a passive component for example only including IC die interconnect structures having a sub-micron lateral pitch. In other embodiments, IC die 1065 may include active electrical and/or optical devices. IC die 1065 may be in electrical contact a through-via 1050, or not. IC die 1065 further comprises a hybrid-bonding surface exposed at front-side of primary substrate 1010 with a remainder of IC die 1065 being substantially embedded within primary substrate 1010.

Assembly 1701 further includes IC die 1091 coupled to primary substrate 1010 and IC die 1065. IC die 1091 may be any ASIC or memory IC, for example. In some embodiments IC die 1091 is a processing unit (xPU), such as any known multi-core processor. EIC die 950, adjacent to IC die 1091, is electrically coupled to primary substrate 1010 through metallization features 965 on substrate surface 1012 that are bonded across the interface HBI₂ to metallization features 1055. Other metallization features 965 may be similarly directly bonded to metallization features of IC die 1065. IC die 1065 may therefore be electrically coupled to each of IC die 1091 and EIC 905 through interface HBI₂. EIC 905 is further coupled to a PIC die comprising PIC structure 200 through interface HBI₁, substantially as described above. Optical coupler 850, adjacent to interface HBI₂, and protruding from a surface of PIC structure 200, is further assembled to a single mode or multimode optical fiber 1080, for example by means of a fiber connector 1075. Fiber connector 1075 may, for example, be affixed to assembly 1701 such that optical fiber 1080 is optically coupled with optical coupler 850.

Assembly 1701 may further include one or more additional IC die 1092, which may comprise passive and/or active electrical and/or optical devices. In some embodiments, IC die 1092 is directly bonded to a second (e.g., backside) surface of IC die 1091, for example through bonding metallization features and bonding dielectric materials joined along bonding interface HBI₁.

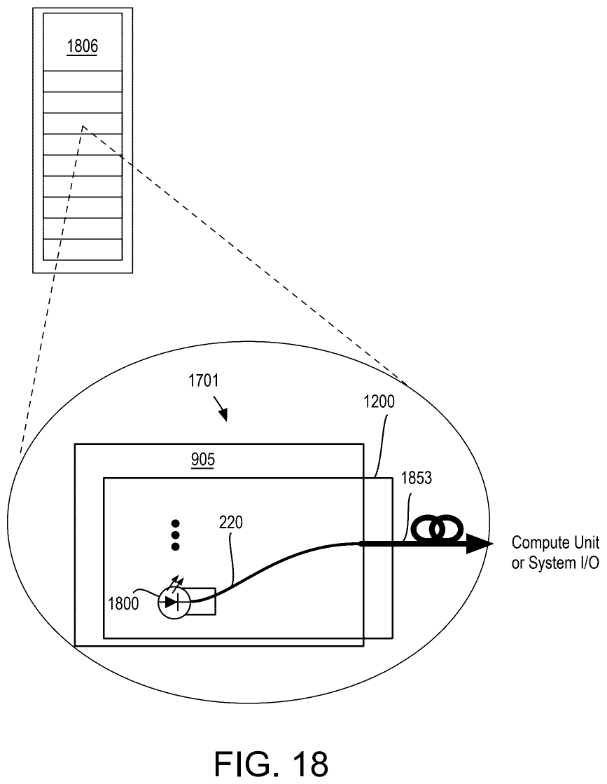

FIG. 18 illustrates a data server platform 1806 employing an optical link with one or more OEIC assembly 1701, for example including a PIC die comprising a PIC structure 1200 and directly bonded to an EIC die, as described elsewhere herein. Platform 1806 may be any commercial server, for example including any number of high-performance computing platforms or compute units networked together for electronic data processing. As shown in the expanded view, PIC structure 1200 comprises an optical emitter (e.g., laser source) 1800 optically coupled through planar waveguide 220 to an optical fiber 1853, for example through top-side coupling or edge output coupler.

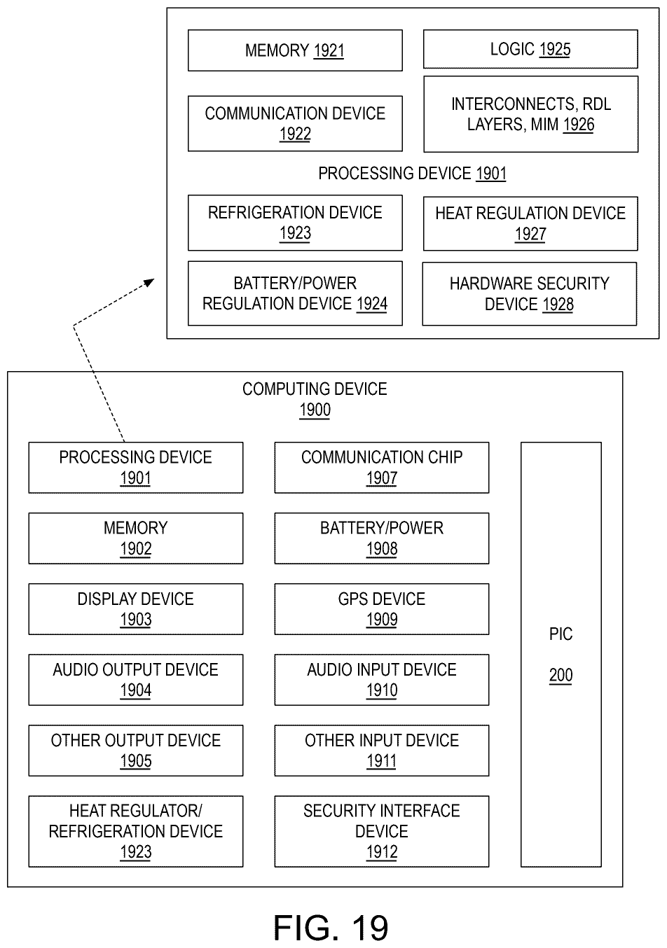

FIG. 19 is a block diagram of a computing device 1900 in accordance with some embodiments. For example, one or more components of computing device 1900 may include any of the PIC die and EIC die discussed elsewhere herein. A number of components are illustrated in FIG. 19, but any one or more of these components may be omitted or duplicated, as suitable for the application. In some embodiments, some of the components included in computing device 1900 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1900 may not include one or more of the components illustrated in FIG. 19, but computing device 1900 may include interface circuitry for coupling to the one or more components. For example, computing device 1900 may not include a display device 1903, but may include display device interface circuitry (e.g., a connector and driver circuitry) to which display device 1903 may be coupled.

Computing device 1900 may include a processing device 1901 (e.g., one or more processing devices). As used herein, the term processing device or processor indicates a device that processes electronic data from registers and/or memory to transform that electronic data into other electronic data that may be stored in registers and/or memory. Processing device 1901 may include a memory 1902, a communication device 1922, a refrigeration/active cooling device 1923, a battery/power regulation device 1924, logic 1925, interconnects 1926, a heat regulation device 1927, and a hardware security device 1928.

Processing device 1901 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1901 may include a memory 1921, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1901 shares a package with memory 1902. This memory may be used as cache memory and may include embedded dynamic random-access memory (eDRAM) or spin transfer torque magnetic random-access memory (STT-M RAM).

Computing device 1900 may include a heat regulation/refrigeration device 1923. Heat regulation/refrigeration device 1923 may maintain processing device 1901 (and/or other components of computing device 1900) at a predetermined low temperature during operation. This predetermined low temperature may be any temperature discussed elsewhere herein.

In some embodiments, computing device 1900 may include a communication chip 1907 (e.g., one or more communication chips). For example, the communication chip 1907 may be configured for managing wireless communications for the transfer of data to and from computing device 1900. The term “wireless” and its derivatives may be used to describe circuits, devices, systems, methods, techniques, communications channels, etc., that may communicate data through the use of modulated electromagnetic radiation through a nonsolid medium.

Computing device 1900 includes composite PIC-EIC structure 900 or 1600, for example having one of the photonic integrated circuit structures directly bonded to an electronic integrated circuit structure, for example as described elsewhere herein. Composite structure 900 or 1600 may facilitate communication to/from one or more instances of processing device 1901 and/or to/from one or more instances of memory 1902. Composite structure 900 or 1600 may facilitate communication to/from computing device 1900 to another such computing device networked to computing device 1900 through optical fiber.

Computing device 1900 may include battery/power circuitry 1908. Battery/power circuitry 1908 may include one or more energy storage devices (e.g., batteries or capacitors) and/or circuitry for coupling components of computing device 1900 to an energy source separate from computing device 1900 (e.g., AC line power).

Computing device 1900 may include a display device 1903 (or corresponding interface circuitry, as discussed above). Display device 1903 may include any visual indicators, such as a heads-up display, a computer monitor, a projector, a touchscreen display, a liquid crystal display (LCD), a light-emitting diode display, or a flat panel display, for example.

Computing device 1900 may include an audio output device 1904 (or corresponding interface circuitry, as discussed above). Audio output device 1904 may include any device that generates an audible indicator, such as speakers, headsets, or earbuds, for example.

Computing device 1900 may include an audio input device 1910 (or corresponding interface circuitry, as discussed above). Audio input device 1910 may include any device that generates a signal representative of a sound, such as microphones, microphone arrays, or digital instruments (e.g., instruments having a musical instrument digital interface (MIDI) output).

Computing device 1900 may include a global positioning system (GPS) device 1909 (or corresponding interface circuitry, as discussed above). GPS device 1909 may be in communication with a satellite-based system and may receive a location of computing device 1900, as known in the art.

Computing device 1900 may include another output device 1905 (or corresponding interface circuitry, as discussed above). Examples include an audio codec, a video codec, a printer, a wired or wireless transmitter for providing information to other devices, or an additional storage device.

Computing device 1900 may include another input device 1911 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1900 may include a security interface device 1912. Security interface device 1912 may include any device that provides security measures for computing device 1900 such as intrusion detection, biometric validation, security encode or decode, managing access lists, malware detection, or spyware detection.

Computing device 1900, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples, an apparatus comprises a first IC die comprising first and second regions over an underlying device layer. The first region comprises a plurality of first metal features within an adjacent first dielectric material layer. The second region comprises a topographic feature extending a height of at least 5 μm above the device layer. The apparatus comprises a second IC die comprising a plurality of second metal features within an adjacent second dielectric material layer. Ones of the second metal features are in direct contact with corresponding ones of the first metal features at a bond interface. The second dielectric material layer is in direct contact with the first dielectric material layer at the bond interface.

In second examples, for any of the first examples the topographic feature is exposed on a surface of the second region.

In third examples, for any of the first through second examples the topographic feature is a mechanical member of a MEMs device or an optical member of a photonic device, and the second IC die is an electronic integrated circuit (EIC) comprising CMOS circuitry.

In fourth examples, for any of the third examples the first IC die is a photonic IC (PIC) die and the topographic feature is an optical coupler.

In fifth examples, for any of the fourth examples the optical coupler comprises a tapered optical waveguide and wherein the device layer comprises a planar optical waveguide optically coupled to the tapered optical waveguide.

In sixth examples, for any of the third through fifth examples the PIC die comprises one or more of a resistive heater or metal-insulator-metal (MIM) capacitor, and wherein the resistive heater or MIM capacitor is coupled to the CMOS circuitry through the bond interface.

In seventh examples, for any of the first through sixth examples the topographic feature is adjacent to a sidewall of first dielectric material located within the first region between the first metal features and the device layer.

In eighth examples, for any of the seventh examples the bond interface is above the height of the topographic feature.

In ninth examples, for any of the eighth examples the first metal features are electrically coupled to a conductive via that extends completely through the first dielectric material.

In tenth examples, for any of the seventh through ninth examples the first dielectric material is separated from a second dielectric material within the first region by an intervening etch stop layer, and wherein the etch stop layer is on a sidewall of the second dielectric material.

In eleventh examples, for any of the seventh through tenth examples the bond interface is below the height of the topographic feature.

In twelfth examples, an apparatus comprises an electronic integrated circuit (EIC), and a photonic integrated circuit (PIC) comprising a first region directly bonded to a first side of the EIC through a plurality of metallization features joined at a first bond interface. The PIC comprises a planar optical waveguide and an optical coupler coupled to a length of the planar optical waveguide. The optical coupler is with a second region of the PIC, adjacent to the first region, and protrudes from a surface of the PIC beyond an edge of the EIC. The EIC comprises a second, opposite, side comprising a second plurality of metallization features to directly bond the EIC to a host substrate.

In thirteenth examples, for any of the twelfth examples the optical coupler comprises an optical grating or tapered optical waveguide that is to interface with an optical fiber.

In fourteenth examples, for any of the twelfth through thirteenth examples the optical coupler protrudes from the surface of the PIC to a height above a plane of the planar optical waveguide that exceeds a height of the bond interface.

In fifteenth examples, for any of the twelfth through fourteenth examples the bond interface is a first height above a plane of the planar optical waveguide exceeding a second height that the optical coupler protrudes from the surface of the PIC.

In sixteenth examples, a system comprises a host substrate directly bonded to a first side of and electronic integrated circuit (EIC) through a plurality of first metallization features joined at a first bond interface. The apparatus comprises a photonic integrated circuit (PIC) comprising a first region directly bonded to a second side of the EIC through a plurality of second metallization features joined at a second bond interface. The PIC comprises a planar optical waveguide, and an optical coupler coupled to a length of the planar optical waveguide. The optical coupler is with a second region of the PIC, adjacent to the first region, and protrudes from a surface of the PIC beyond an edge of the EIC. The apparatus comprises a fiber connector affixed to the PIC. The fiber connector is within a plane of the EIC between the host substrate and the PIC.

In seventeenth examples, for any of the sixteenth examples the system comprises optical fiber affixed to the fiber connector and optically coupled to the optical coupler.

In eighteenth examples, for any of the sixteenth through seventeenth examples the system comprises one or more IC die adjacent to the EIC and directly bonded to the host substrate.

In nineteenth examples, for any of the eighteenth examples the one or more IC die adjacent to the EIC comprises a multi-core processor.

In twentieth examples, for any of the sixteenth through nineteenth examples the system comprises an IC die embedded within the host substrate and directly bonded to the EIC.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. An apparatus, comprising:
a first IC die comprising first and second regions over an underlying device layer, wherein:
the first region comprises a plurality of first metal features within an adjacent first dielectric material layer; and
the second region comprises a topographic feature extending a height of at least 5 μm above the device layer; and
a second IC die comprising a plurality of second metal features within an adjacent second dielectric material layer, wherein ones of the second metal features are in direct contact with corresponding ones of the first metal features at a bond interface, and wherein the second dielectric material layer is in direct contact with the first dielectric material layer at the bond interface.

2. The apparatus of claim 1, wherein the topographic feature is exposed on a surface of the second region.

3. The apparatus of claim 1, wherein the topographic feature is a mechanical member of a MEMs device or an optical member of a photonic device, and wherein the second IC die is an electronic integrated circuit (EIC) comprising CMOS circuitry.

4. The apparatus of claim 3, wherein the first IC die is a photonic IC (PIC) die and the topographic feature is an optical coupler.

5. The apparatus of claim 4, wherein the optical coupler comprises a tapered optical waveguide and wherein the device layer comprises a planar optical waveguide optically coupled to the tapered optical waveguide.

6. The apparatus of claim 3, wherein the PIC die comprises one or more of a resistive heater or metal-insulator-metal (MIM) capacitor, and wherein the resistive heater or MIM capacitor is coupled to the CMOS circuitry through the bond interface.

7. The apparatus of claim 1, wherein the topographic feature is adjacent to a sidewall of first dielectric material located within the first region between the first metal features and the device layer.

8. The apparatus of claim 7, wherein the bond interface is above the height of the topographic feature.

9. The apparatus of claim 8, wherein the first metal features are electrically coupled to a conductive via that extends completely through the first dielectric material.

10. The apparatus of claim 7, wherein the first dielectric material is separated from a second dielectric material within the first region by an intervening etch stop layer, and wherein the etch stop layer is on a sidewall of the second dielectric material.

11. The apparatus of claim 7, wherein the bond interface is below the height of the topographic feature.

12. An apparatus, comprising:
an electronic integrated circuit (EIC); and
a photonic integrated circuit (PIC) comprising a first region directly bonded to a first side of the EIC through a plurality of metallization features joined at a first bond interface, wherein the PIC comprises:
a planar optical waveguide; and
an optical coupler coupled to a length of the planar optical waveguide, wherein the optical coupler is with a second region of the PIC, adjacent to the first region, and protrudes from a surface of the PIC beyond an edge of the EIC; and
wherein the EIC comprises a second, opposite, side comprising a second plurality of metallization features to directly bond the EIC to a host substrate.

13. The apparatus of claim 12, wherein the optical coupler comprises an optical grating or tapered optical waveguide that is to interface with an optical fiber.

14. The apparatus of claim 12, wherein the optical coupler protrudes from the surface of the PIC to a height above a plane of the planar optical waveguide that exceeds a height of the bond interface.

15. The apparatus of claim 12, wherein the bond interface is a first height above a plane of the planar optical waveguide exceeding a second height that the optical coupler protrudes from the surface of the PIC.

16. A system comprising:
a host substrate directly bonded to a first side of and electronic integrated circuit (EIC) through a plurality of first metallization features joined at a first bond interface;
a photonic integrated circuit (PIC) comprising a first region directly bonded to a second side of the EIC through a plurality of second metallization features joined at a second bond interface, wherein the PIC comprises:
a planar optical waveguide; and
an optical coupler coupled to a length of the planar optical waveguide, wherein the optical coupler is with a second region of the PIC, adjacent to the first region, and protrudes from a surface of the PIC beyond an edge of the EIC; and
a fiber connector affixed to the PIC, wherein the fiber connector is within a plane of the EIC between the host substrate and the PIC.

17. The system of claim 16, further comprising optical fiber affixed to the fiber connector and optically coupled to the optical coupler.

18. The system of claim 16, further comprising one or more IC die adjacent to the EIC and directly bonded to the host substrate.

19. The system of claim 18, wherein the one or more IC die adjacent to the EIC comprises a multi-core processor.

20. The system of claim 16, further comprising an IC die embedded within the host substrate and directly bonded to the EIC.
